(19) United States
(12) Patent Application Publication
(10) Pub. No.: US 2026/0164959 A1
(43) Pub. Date: Jun. 11, 2026

(54) DISPLAY PANEL AND METHOD FOR PREPARING SAME, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Shun ZHANG, Beijing (CN); Yudiao CHENG, Beijing (CN); Fengli JI, Beijing (CN); Jiangtao DENG, Beijing (CN)

(21) Appl. No.: 18/708,565

(22) PCT Filed: Aug. 29, 2023
(86) PCT No.: PCT/CN2023/115571

§ 371 Date: May 8, 2024

(51) Int. Cl. H10K 59/131; H10K 59/12; H10K 59/121; H10K 59/126

(52) U.S. Cl. CPC H10K 59/131; H10K 59/1201; H10K 59/1213; H10K 59/126

(57) ABSTRACT

Provided is a display panel, including a substrate, a conductive shielding layer, a shift register circuit, a first potential line, and a first insulative layer. The shift register circuit includes a plurality of first-type transistors. An orthographic projection of the conductive shielding layer on the substrate is at least within a frame region, covers orthographic projections of at least a portion of the first-type transistors on the substrate, and is at least partially overlapped with an orthographic projection of the first potential line on the substrate. A first opening is formed in the first insulative layer. An orthographic projection of the first opening on the substrate is within an overlap region between the orthographic projections of the conductive shielding layer and the first potential line. At least a local region of the conductive shielding layer is electrically connected to the first potential line via the first opening.

### CROSS-REFERENCE TO RELATED APPLICATION

The application is a U.S. national stage of international application No. PCT/CN 2023/115571, filed on Aug. 29, 2023, the content of which is herein incorporated by reference in its entirety.

### TECHNICAL FIELD

The present disclosure relates to the field of display technologies, and in particular, relates to a display panel and a method for preparing the same, and a display device.

### BACKGROUND

Organic light-emitting diode (OLED) displays have received considerable attention for their advantages of self-luminescence, low power consumption, lightweight, flexibility, brilliant colors, high contrast, and fast response.

### SUMMARY

According to some embodiments of the present disclosure, a display panel is provided. The display panel has a display region and a frame region, wherein the frame region surrounds the display region, and the display panel includes:
a substrate;
a conductive shielding layer disposed on a side of the substrate, wherein an orthographic projection of the conductive shielding layer on the substrate is at least within the frame region;
a shift register circuit disposed in the frame region and on a side, going away from the substrate, of the conductive shielding layer;
a first potential line disposed in the frame region and on the side, going away from the substrate, of the conductive shielding layer; and
a first insulative layer disposed between the conductive shielding layer and the first potential line and the shift register circuit; wherein
the shift register circuit and the first potential line are successively arranged along a direction away from the display region;
the shift register circuit includes a plurality of first-type transistors, and the orthographic projection of the conductive shielding layer on the substrate covers orthographic projections of at least a portion of the first-type transistors on the substrate; and
the orthographic projection of the conductive shielding layer on the substrate is at least partially overlapped with an orthographic projection of the first potential line on the substrate, a first opening is formed in the first insulative layer, an orthographic projection of the first opening on the substrate being within an overlap region between the orthographic projections of the conductive shielding layer and the first potential line, and at least a local region of the conductive shielding layer is electrically connected to the first potential line via the first opening.

In some embodiments, the first potential line includes a first conductive layer and a second conductive layer, wherein the first conductive layer and the second conductive layer are stacked successively away from the substrate, an orthographic projection of the first conductive layer on the substrate being at least partially overlapped with an orthographic projection of the second conductive layer on the substrate, and the first conductive layer is electrically connected to at least a local region of the conductive shielding layer via the first opening; and the display panel further includes a first planarization layer disposed between the first conductive layer and the second conductive layer, wherein a second opening is formed in the first planarization layer, an orthographic projection of the second opening on the substrate being within an overlap region between the orthographic projections of the first conductive layer and the second conductive layer, and the first conductive layer is electrically connected to the second conductive layer via the second opening.

In some embodiments, the first potential line includes a first conductive layer, a second conductive layer, and a third conductive layer, wherein the first conductive layer, the third conductive layer, and the second conductive layer are stacked successively away from the substrate, orthographic projections of any adjacent two of the first conductive layer, the third conductive layer, and the second conductive layer on the substrate being at least partially overlapped, and the first conductive layer is electrically connected to at least a local region of the conductive shielding layer via the first opening; the display panel further includes a first planarization layer disposed between the first conductive layer and the third conductive layer, wherein a second opening is formed in the first planarization layer, an orthographic projection of the second opening on the substrate being within an overlap region between the orthographic projections of the first conductive layer and the third conductive layer, and the first conductive layer is electrically connected to the third conductive layer via the second opening; and the display panel further includes a second planarization layer disposed between the third conductive layer and the second conductive layer, wherein a third opening is formed in the second planarization layer, an orthographic projection of the third opening on the substrate being within an overlap region between the orthographic projections of the second conductive layer and the third conductive layer, and the third conductive layer is electrically connected to the second conductive layer via the third opening.

In some embodiments, each of the first-type transistors includes a gate electrode, an active layer, a first electrode, and a second electrode, wherein the first electrode and the second electrode are disposed in a same layer, the gate electrode, the active layer, and the first electrode are respectively disposed in different layers, and the first conductive layer, the first electrode, and the second electrode are disposed in a same layer; the display panel further includes a light-emitting element disposed in the display region, wherein the light-emitting element includes a first electrode, a light-emitting functional layer, and a second electrode that are stacked successively away from the substrate, the second conductive layer and the first electrode are disposed in a same layer, the second electrode extends to the frame region, and an orthographic projection of second electrode on the substrate is partially overlapped with the orthographic projection of the second conductive layer on the substrate; and the display panel further includes a second insulative layer disposed between the first electrode and the second electrode, wherein the second insulative layer extends from the display region to the frame region, a fourth opening is formed in a portion, disposed in the frame region, of the second insulative layer, and the second electrode is electrically connected to the second conductive layer via the fourth opening.

In some embodiments, the display panel further includes a pixel circuit disposed in the display region and between the light-emitting element and the substrate; wherein the pixel circuit includes a conductive connecting structure and a plurality of second-type transistors, wherein the plurality of second-type transistors and the plurality of first-type transistors are disposed in a same layer, and the conductive connecting structure is disposed on a side, going away from the substrate, of the second-type transistors; the first planarization layer extends between the second-type transistors and the conductive connecting structure, wherein a fifth opening is formed in a portion, disposed in the display region, of the first planarization layer, and a first electrode of each of the second-type transistors is electrically connected to the conductive connecting structure via the fifth opening; the second planarization layer extends between the conductive connecting structure and the first electrode, wherein a sixth opening is formed in a portion, disposed in the display region, of the second planarization layer, and the conductive connecting structure is electrically connected to the first electrode via the sixth opening; and the third conductive layer and the conductive connecting structure are disposed in a same layer.

In some embodiments, the display panel further includes a first dam and a second dam that are disposed in the frame region and on a side, going away from the substrate, of the second conductive layer; wherein the first dam and the second dam are successively arranged and spaced apart from each other along the direction away from the display region, and orthographic projections of the first dam and the second dam on the substrate are at least partially overlapped with the orthographic projection of the first potential line on the substrate; and the orthographic projection of the first opening on the substrate is disposed between the orthographic projection of the first dam on the substrate and an orthographic projection of the shift register circuit on the substrate.

In some embodiments, the display panel further includes a first dam and a second dam that are disposed in the frame region and on a side, going from the substrate, of the second conductive layer; wherein the first dam and the second dam are successively arranged and spaced apart from each other along the direction away from the display region, and orthographic projections of the first dam and the second dam on the substrate are at least partially overlapped with the orthographic projection of the first potential line on the substrate; and the orthographic projection of the first opening on the substrate is disposed between the orthographic projections of the first dam and the second dam on the substrate.

In some embodiments, the first potential line surrounds at least three sides of the frame region outside of the display region; and the first openings are continuously distributed along an extension direction of the first potential line.

In some embodiments, the first potential line surrounds at least three sides of the frame region outside of the display region; and a plurality of the first openings are provided, wherein the plurality of the first openings are spaced apart successively along an extension direction of the first potential line.

In some embodiments, the conductive shielding layer disposed in the frame region is planar; and the orthographic projection of the conductive shielding layer on the substrate at least covers orthographic projections of all of the first-type transistors in the shift register circuit on the substrate.

In some embodiments, a plurality of hollowed-out portions are formed in the conductive shielding layer disposed in the frame region; and an orthographic projection of a region, other than the plurality of hollowed-out portions, of the conductive shielding layer on the substrate at least covers orthographic projections of all of the first-type transistors in the shift register circuit on the substrate.

In some embodiments, the conductive shielding layer disposed in the frame region includes a first region and a second region, the first region and the second region being discontiguous from each other; wherein an orthographic projection of the first region on the substrate is at least partially overlapped with an orthographic projection of the first conductive layer on the substrate, and an orthographic projection of the second region on the substrate is at least partially overlapped with an orthographic projection of the shift register circuit on the substrate; and the first region is electrically connected to the first conductive layer via the first opening, and the second region is electrically connected to a second potential line.

In some embodiments, a plurality of the first openings are provided, the plurality of the first openings being successively spaced apart along a line width direction, away from the display region, of the first potential line.

In some embodiments, the first potential line surrounds at least three sides of the frame region outside of the display region; and each of the first openings is continuously distributed along an extension direction of the first potential line.

In some embodiments, the first potential line surrounds at least three sides of the frame region outside of the display region; and each of the first openings includes a plurality of sub-openings, the plurality of sub-openings of each of the first openings being spaced apart successively along the extension direction of the first potential line.

In some embodiments, the display panel further has a bonding connecting region disposed at least one side of the frame region outside of the display region; wherein the display panel further includes a plurality of first traces and a plurality of the second potential lines, wherein the plurality of first traces, the plurality of the second potential lines, and the first potential line are at least partially disposed in the bonding connecting region, the plurality of first traces and the plurality of the second potential lines are disposed on the side, going away from the substrate, of the conductive shielding layer, and the plurality of first traces are electrically connected to the shift register circuit; and the conductive shielding layer further includes a third region, wherein an orthographic projection of the third region on the substrate is disposed in the bonding connecting region, the orthographic projection of the third region on the substrate at least covers orthographic projections of the plurality of first traces on the substrate, the third region is discontiguous from the first region and the second region, and the third region is electrically connected to the first potential line disposed in the bonding connecting region, or the third region is electrically connected to the second potential line disposed in the bonding connecting region.

In some embodiments, the conductive shielding layer further includes a fourth region; wherein an orthographic projection of the fourth region on the substrate is disposed in the display region; the orthographic projection of the fourth region on the substrate covers orthographic projections of at least a portion of the second-type transistors on the substrate; and the fourth region is discontiguous from the first region, the second region, and the third region, and the fourth region is electrically connected to the second potential line.

In some embodiments, the shift register circuit includes a first gate drive shift register circuit, a light-emitting control shift register circuit, and a second gate drive shift register circuit.

According to some embodiments of the present disclosure, a display device is provided. The display device includes the display panel as described above.

According to some embodiments of the present disclosure, a method for preparing a display panel is provided. The method includes:
preparing a conductive shielding layer on a substrate; and
preparing a first insulative layer, a shift register circuit, and a first potential line on a side, going from the substrate, of the conductive shielding layer; wherein
preparing the shift register circuit includes preparing a plurality of first-type transistors, wherein an orthographic projection of the conductive shielding layer on the substrate covers orthographic projections of at least a portion of the first-type transistors on the substrate; and preparing the first insulative layer includes preparing a pattern of a first opening, wherein at least a local region of the conductive shielding layer is electrically connected to the first potential line via the first opening.

### BRIEF DESCRIPTION OF DRAWINGS

The accompanying drawings, facilitating understanding of the embodiments of the present disclosure and constituting a part of the specification, serve for explaining the present disclosure in conjunction with the embodiments of the present disclosure, and do not constitute any limitation to the present disclosure. The above and other features and advantages will become more apparent to those skilled in the art by describing the detailed exemplary embodiments with reference to the accompanying drawings. In the accompanying drawings:

FIG. 1a is a schematic diagram of a principle in which static electricity causes a forward bias in the characteristics of a transistor in a gate shift register circuit;

FIG. 1b is a circuit schematic of a gate shift register circuit;

FIG. 1c is a comparison schematic between a scenario where a gate shift register circuit outputs pulses normally such that no screen flicker occurs and a scenario where a gate shift register circuit generates a multiple-pulse output such that screen flicker occurs;

FIG. 2a is a top view of a display panel according to some embodiments of the present disclosure;

FIG. 2b is a schematic structural diagram of a section along a section line AA′ in FIG. 2a;

FIG. 2c is a schematic structural diagram of a section along a section line BB′ in FIG. 2a;

FIG. 3a is a circuit diagram of a pixel circuit according to some embodiments of the present disclosure;

FIG. 3b is a sectional schematic structural diagram of a local region of a shift register circuit and a local region within a display region according to some embodiments of the present disclosure;

FIG. 4a is another schematic structural diagram of a section along a section line AA′ in FIG. 2a;

FIG. 4b is another schematic structural diagram of a section along a section line BB′ in FIG. 2a;

FIG. 5 a is an enlarged top view of a portion C in FIG. 2 a;

FIG. 5b is still another schematic structural diagram of a section along a section line AA′ in FIG. 2a;

FIG. 5c is yet still another schematic diagram of a section along a section line AA′ in FIG. 2a;

FIG. 5 d is another enlarged top view of a portion C in FIG. 2 a;

FIG. 6a is another top view of a display panel according to some embodiments of the present disclosure;

FIG. 6b is still another top view of a display panel according to some embodiments of the present disclosure;

FIG. 6c is a schematic structural diagram of a section along a section line DD′ in FIG. 6b;

FIG. 6d is a schematic structural diagram of a section along a section line DD′ in FIG. 6b;

FIG. 7a is a local top view of a region where a shift register circuit is disposed according to some embodiments of the present disclosure;

FIG. 7b is another local top view of a region where a shift register circuit is disposed according to some embodiments of the present disclosure;

FIG. 8a is still another local top view of a region where a shift register circuit is disposed according to some embodiments of the present disclosure;

FIG. 8b is yet still another local top view of a region where a shift register circuit is disposed according to some embodiments of the present disclosure;

FIG. 9a is yet still another schematic diagram of a section along a section line AA′ in FIG. 2a;

FIG. 9b is yet still another schematic diagram of a section along a section line AA′ in FIG. 2a;

FIG. 10a is yet still another top view of a display panel according to some embodiments of the present disclosure;

FIG. 10b is a schematic structural diagram of a section along a section line EE′ in FIG. 10a;

FIG. 10c is another schematic structural diagram of a section along a section line EE′ in FIG. 10a;

FIG. 10d is yet still another top view of a display panel according to some embodiments of the present disclosure;

FIG. 11a is a top view of a bonding connecting region of a display panel according to some embodiments of the present disclosure;

FIG. 11 b is an enlarged schematic diagram of a portion F of FIG. 11 a;

FIG. 11 c is an enlarged schematic diagram of a portion G of FIG. 11 a; and

FIG. 11d is a top view of a third region of a conductive shielding layer within a bonding connecting region of a display panel according to some embodiments of the present disclosure.

### DETAILED DESCRIPTION

For a better understanding of the technical solutions of the embodiments of the present disclosure by those skilled in the art, a display panel and method for preparing the same, and a display device are described hereinafter in further detail in conjunction with the accompanying drawings and specific embodiments.

Embodiments of the present disclosure will be fully described hereinafter with reference to the accompanying drawings, but the embodiments shown may be embodied in different forms and should not be construed to be any limitation to the embodiments of the present disclosure. Instead, these embodiments are provided for the purpose of making the present disclosure thorough and complete and will enable those skilled in the art to fully understand the scope of the present disclosure.

Embodiments of the present disclosure are not limited to the embodiments illustrated in the accompanying drawings but rather include modifications to configurations based on manufacturing processes. Accordingly, the regions exemplified in the accompanying drawings have schematic properties, and the shapes of the regions shown in the drawings exemplify specific shapes of the regions but are not intended to be limiting.

Flexible active-matrix organic light-emitting diode (AMOLED) wearable products (e.g., watches, bracelets, and the like.) are provided with a full-face copper foil on the back side to channel and discharge static electricity accumulated by the product. However, AMOLED wearable products have near-field communication (NFC) and antennas on the back side of the copper foil for ease of wear.

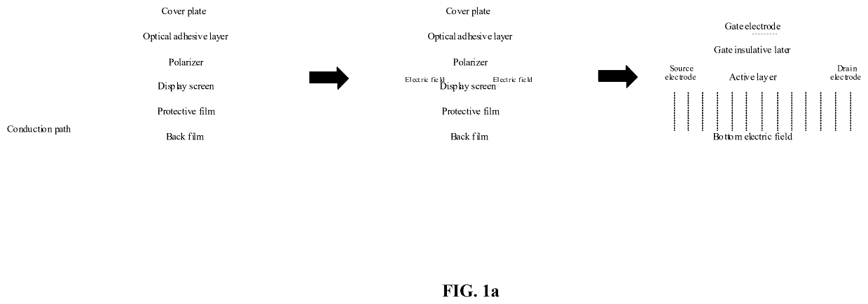

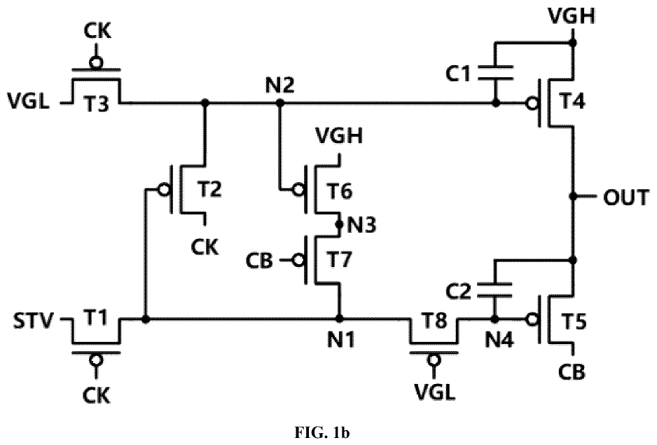

The arrangement of the full-face copper foil on the back side of the wearable product shields the NFC signal and the antenna signal, which affects the normal transmission of the NFC signal and the antenna signal. Therefore, there is a tendency to provide no copper foil or local copper foil on the back side of the wearable product. FIG. 1a is a schematic diagram of a principle in which static electricity causes a forward bias in the characteristics of a transistor in a gate shift register circuit. FIG. 1b is a circuit schematic of a gate shift register circuit. FIG. 1c is a comparison schematic between a scenario where a gate shift register circuit outputs pulses normally such that no screen flicker occurs and a scenario where a gate shift register circuit generates a multiple-pulse output such that screen flicker occurs. Referring to FIG. 1a, FIG. 1b, and FIG. 1c, no copper foil or local copper foil results in a weakened antistatic capability of the screen body of the wearable product. In this case, the negative electrostatic charges are easily accumulated and remain in the backside film layer of the screen body, such that the characteristics of the transistor (i.e., Gate GOA TFT) in the gate shift register circuit of the screen body become forward biased, and thus the gate shift register circuit generates a multiple-pulse output (which is mainly affected by the forward bias of T2), which induces a screen flicker defect.

Referring to FIG. 1a, in a case where the defective phenomenon is reproduced by an electrostatic field test of a certain intensity (e.g., −6 KV) or rubbing the cover plate of the screen body of the wearing product by a belt, essentially, the negative charges are accumulated on the surface of the cover plate of the screen body. The negative charges are transmitted downward along the sides of the edges around the screen body and finally accumulated in the overall backing film (e.g., foam and copper foil) at the back side of the screen body.

At present, the static protection measures for AMOLED wearable products mainly include using a metal internal frame for the whole machine and adding a copper foil locally on the back side of the screen body.

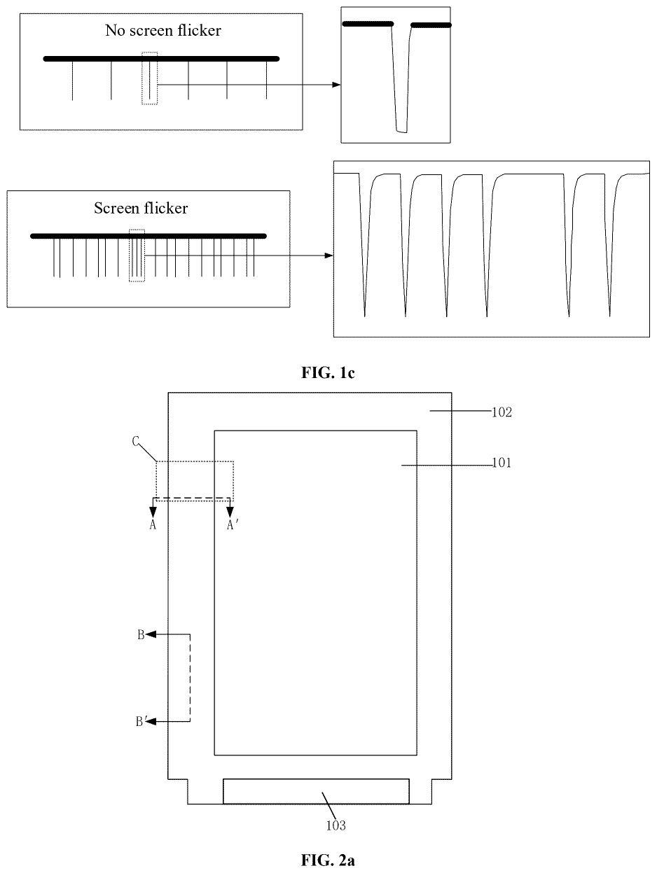

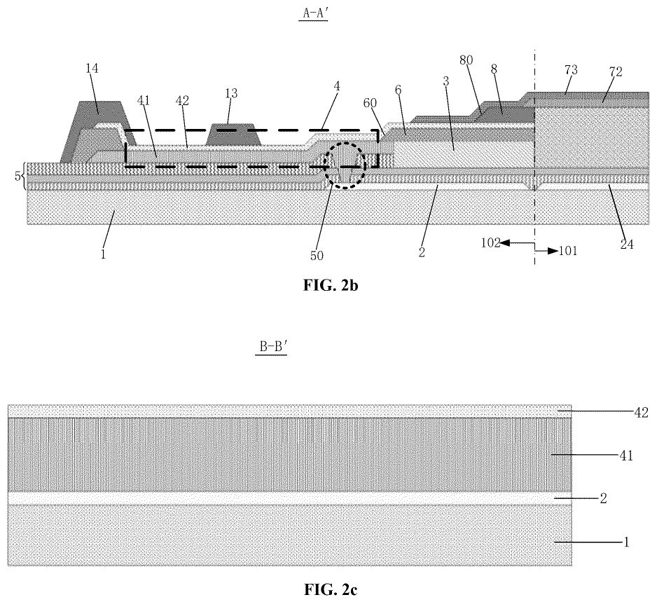

To address the current problem of the screen flicker defect caused by no copper foil or local copper foil on the back side of AMOLED wearable products, in a first aspect, some embodiments of the present disclosure provide a display panel. FIG. 2a is a top view of a display panel according to some embodiments of the present disclosure. FIG. 2b is a schematic structural diagram of a section along a section line AA′ in FIG. 2a. FIG. 2c is a schematic structural diagram of a section along a section line BB′ in FIG. 2a. Referring to FIG. 2a, FIG. 2b, and FIG. 2c, the display panel has a display region 101 and a frame region 102. The frame region 102 surrounds the display region 101. The display panel includes a substrate 1; a conductive shielding layer 2 disposed on a side of the substrate 1, wherein an orthographic projection of the conductive shielding layer 2 on the substrate 1 is at least within the frame region 102; a shift register circuit 3 disposed in the frame region 102 and disposed on a side, going away from the substrate 1, of the conductive shielding layer 2; a first potential line 4 disposed in the frame region 102 and disposed on the side, going away from the substrate 1, of the conductive shielding layer 2; and a first insulative layer 5 disposed between the conductive shielding layer 2 and the first potential line 4 and the shift register circuit 3. The shift register circuit 3 and the first potential line 4 are disposed successively in a direction away from the display region 101. The shift register circuit 3 includes a plurality of first-type transistors. The orthographic projection of the conductive shielding layer 2 on the substrate 1 covers orthographic projections of at least a portion of the first-type transistors on the substrate 1. The orthographic projection of the conductive shielding layer 2 is at least partially overlapped with an orthographic projection of the first potential line 4 on the substrate 1. A first opening 50 is formed in the first insulative layer 5, and at least a local region of the conductive shielding layer 2 is electrically connected to the first potential line 4 via the first opening 50.

By arranging the conductive shielding layer 2 underneath the shift register circuit 3, the orthographic projection of the conductive shielding layer 2 on the substrate 1 covers the orthographic projection of at least a portion of the first-type transistors in the shift register circuit 3 on the substrate 1, and at least a local region of the conductive shielding layer 2 is electrically connected to the first potential line 4 via the first opening 50, such that the at least a local region of the conductive shielding layer 2 have a first potential. At the same time, the at least a local region of the conductive shielding layer 2 and the first potential line 4 in the first opening 50 are connected and enclosed to form a three-dimensional shielding structure. The three-dimensional shielding structure is capable of forming a shield for at least a portion of the first-type transistors in the shift register circuit 3. In this way, the static electricity accumulated on the back side of the substrate 1 is prevented from affecting the characteristics of the at least a portion of the first-type transistors, such that the screen flicker defect of the display panel is prevented. At the same time, the anti-static capability of the display panel is enhanced, and the anti-static capability of the display panel to avoid the screen flicker defect is improved.

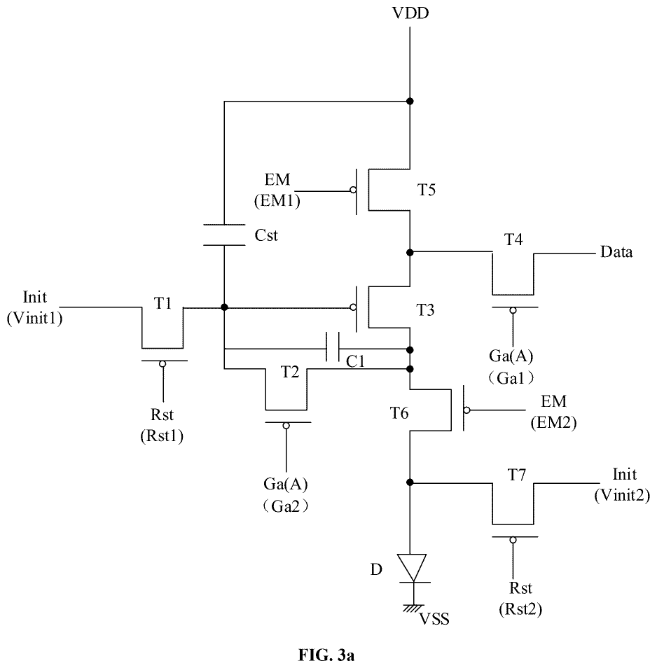

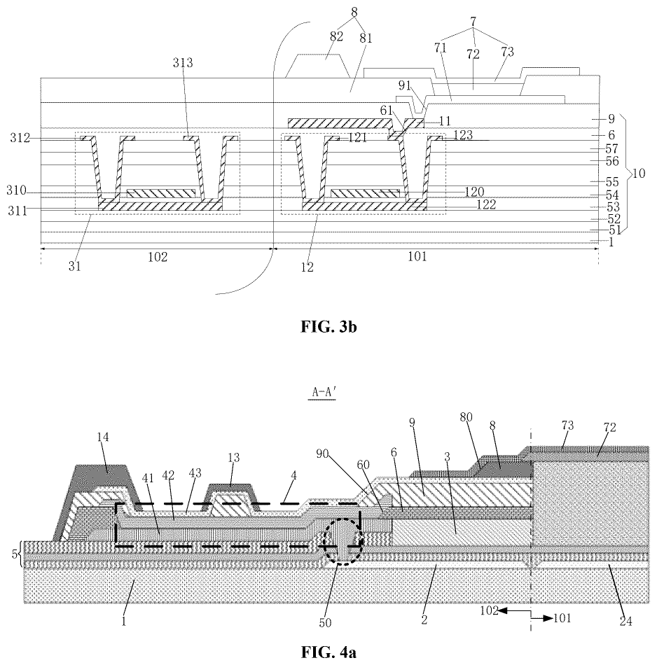

In some embodiments, referring to FIG. 3a, which is a circuit schematic of a pixel circuit according to some embodiments of the present disclosure, the shift register circuit 3 includes a first gate drive shift register circuit, a light-emitting control shift register circuit, and a second gate drive shift register circuit. The first gate drive shift register circuit is configured to provide drive signals for gate electrodes of a second transistor T2 and a fourth transistor T4 in the pixel circuit. The light-emitting control shift register circuit is configured to provide drive signals for gate electrodes of a fifth transistor T5 and a sixth transistor T6 in the pixel circuit. The second gate drive shift register circuit is configured to provide drive signals for gate electrodes of a first transistor T1 and a seventh transistor T7 in the pixel circuit. The first transistor T1 and the second transistor T2 in the pixel circuit are oxide semiconductor thin-film transistors, and the other transistors are amorphous silicon thin-film transistors or polycrystalline silicon thin-film transistors.

In some embodiments, referring to FIGS. 2b and 2c, the first potential line 4 includes a first conductive layer 41 and a second conductive layer 42. The first conductive layer 41 and the second conductive layer 42 are successively stacked away from the substrate 1, and an orthographic projection of the first conductive layer 41 on the substrate 1 is at least partially overlapped with an orthographic projection of the second conductive layer 42 on the substrate 1. The first conductive layer 41 is electrically connected to at least a local region of the conductive shielding layer 2 via the first opening 50. The display panel further includes a first planarization layer 6 disposed between the first conductive layer 41 and the second conductive layer 42. A second opening 60 is formed in the first planarization layer 6, and an orthographic projection of the second opening 60 on the substrate 1 is within an overlap region between the orthographic projections of the first conductive layer 41 and the second conductive layer 42. The first conductive layer 41 and the second conductive layer 42 are electrically connected via the second opening 60.

In some embodiments, referring to FIG. 2b, a portion, disposed in the frame region 102, of the conductive shielding layer 2 is connected as one piece. That is, the portion, disposed in the frame region 102, of the conductive shielding layer 2 is not partitioned. The portion, disposed in the frame region 102, of the conductive shielding layer 2 is electrically connected to the first conductive layer 41 via the first opening 50.

In some embodiments, referring to FIG. 3b, which is a sectional schematic structural diagram of a local region of a shift register circuit and a local region within a display region according to some embodiments of the present disclosure, the first-type transistor 31 includes a gate electrode 310, an active layer 311, a first electrode 312, and a second electrode 313. The first electrode 312 and the second electrode 313 are disposed in the same layer. The gate electrode 310, the active layer 311, and the first electrode 312 are disposed in different layers. The first conductive layer 41, the first electrode 312, and the second electrode 313 are disposed in the same layer. The display panel further includes a light-emitting element 7 disposed in the display region 101. The light-emitting element 7 includes a first electrode 71, a light-emitting function layer 72, and a second electrode 73 that are successively stacked away from the substrate 1. The second conductive layer 42 and the first electrode 71 are disposed in the same layer. The second electrode 73 extends to the frame region 102, and an orthographic projection of the second electrode 73 on the substrate 1 is partially overlapped with an orthographic projection of the second conductive layer 42 on the substrate 1. The display panel further includes a second insulative layer 8 disposed between the first electrode 71 and the second electrode 73, and the second insulative layer 8 extends from the display region 101 to the frame region 102. A fourth opening 80 is formed in a portion, disposed in the frame region 102, of the second insulative layer 8, and the second electrode 73 is electrically connected to the second conductive layer 42 via the fourth opening 80.

In some embodiments, referring to FIG. 3b, the first electrode 71 is an anode of the light-emitting element 7, the second electrode 73 is a cathode of the light-emitting element 7, the second electrode 73 is electrically connected to the first potential line 4, and a potential signal on the first potential line 4 is a low-potential signal, such as VSS.

In some embodiments, referring to FIG. 3b, the first insulative layer 5 extends from the display region 101 to the frame region 102. The first insulative layer 5 includes an inorganic insulative layer 51, a first buffer layer 52, a first gate insulative layer 53, a second gate insulative layer 54, a second buffer layer 55, a third gate insulative layer 56, and an intermediate dielectric layer 57 that are successively stacked along a direction away from the substrate 1. Each film layer of the first insulative layer 5 is made of an inorganic insulative material, such as silicon nitride, silicon oxide, or silicon oxynitride. The second insulative layer 8 includes a pixel defining layer 81 and a support spacer layer 82 that are successively stacked along the direction away from the substrate 1. Each film layer in the second insulative layer 8 is made of an organic resin material, such as polyimide, polyurethane, or the like.

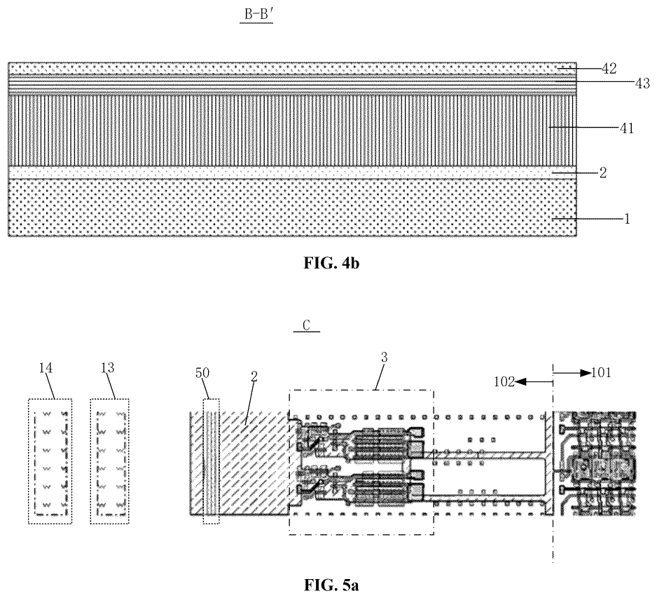

FIG. 4a is another schematic structural diagram of a section along a section line AA′ in FIG. 2a. FIG. 4b is another schematic structural diagram of a section along a section line BB′ in FIG. 2a. In some embodiments, referring to FIG. 4a and FIG. 4b, the first potential line 4 includes a first conductive layer 41, a second conductive layer 42, and a third conductive layer 43. The first conductive layer 41, the third conductive layer 43, and the second conductive layer 42 are successively stacked away from the substrate 1. Orthographic projections of any adjacent two of the first conductive layer 41, the third conductive layer 43, and the second conductive layer 42 on the substrate 1 are at least partially overlapped. The first conductive layer 41 is electrically connected to at least a local region of the conductive shielding layer 2 via the first opening 50. The display panel further includes a first planarization layer 6 disposed between the first conductive layer 41 and the third conductive layer 43. A second opening 60 is formed in the first planarization layer 6. An orthographic projection of the second opening 60 on the substrate 1 is within an overlap region between the orthographic projections of the first conductive layer 41 and the third conductive layer 43, and the first conductive layer 41 and the third conductive layer 43 are electrically connected via the second opening 60. The display panel further includes a second planarization layer 9 disposed between the third conductive layer 43 and the second conductive layer 42. A third opening 90 is formed in the second planarization layer 9, an orthographic projection of the third opening 90 on the substrate 1 is within an overlap region of the orthographic projections of the second conductive layer 42 and the third conductive layer 43, and the third conductive layer 43 and the second conductive layer 42 are electrically connected via the third opening 90.

In some embodiments, referring to FIG. 4a, a portion, disposed in the frame region 102, of the conductive shielding layer 2 is connected as one piece. That is, the portion, disposed in the frame region 102, of the conductive shielding layer 2 is not partitioned. The portion, disposed in the frame region 102, of the conductive shielding layer 2 is electrically connected to the first conductive layer 41 via the first opening 50.

In some embodiments, referring to FIG. 3b, the display panel further includes a pixel circuit 10 disposed in the display region 101 and between the light-emitting element 7 and the substrate 1. The pixel circuit 10 includes a conductive connecting structure 11 and a plurality of second-type transistors 12. The plurality of second-type transistors 12 are disposed in the same layer as the plurality of first-type transistors 31. The conductive connecting structure 11 is disposed on a side, away from the substrate 1, of the second-type transistors 12. The first planarization layer 6 extends between the second-type transistors 12 and the conductive connecting structure 11. A fifth opening 61 is formed in a portion, disposed in the display region 101, of the first planarization layer 6, and a first electrode 121 of the second-type transistor 12 is electrically connected to the conductive connecting structure 11 via the fifth opening 61. The second planarization layer 9 extends between the conductive connecting structure 11 and the first electrode 71. A sixth opening 91 is formed in a portion, disposed in the display region 101, of the second planarization layer 9, and the conductive connecting structure 11 is electrically connected to the first electrode 71 via the sixth opening 91. The third conductive layer 43 and the conductive connecting structure 11 are disposed in the same layer.

In some embodiments, referring to FIG. 3b, the second-type transistor 12 further includes a gate electrode 120, an active layer 122, and a second electrode 123. The first electrode 121 and the second electrode 123 are disposed in the same layer. The gate electrode 120, the active layer 122, and the first electrode 121 are respectively disposed in different layers.

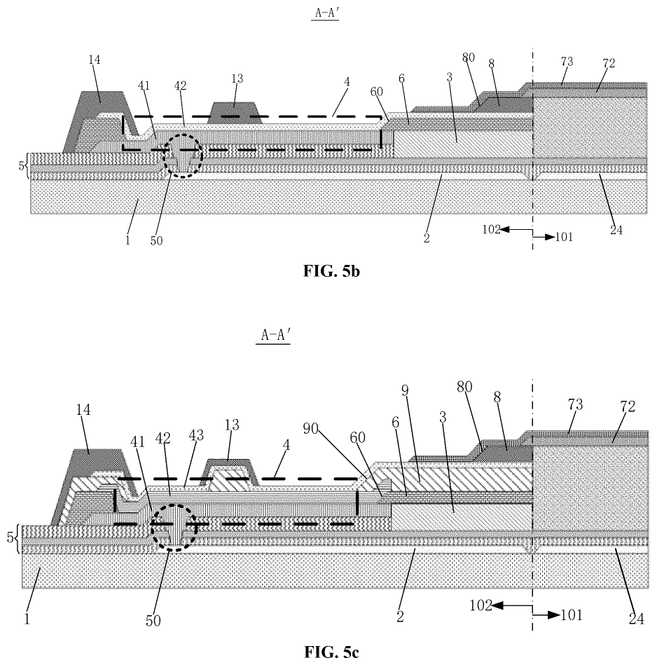

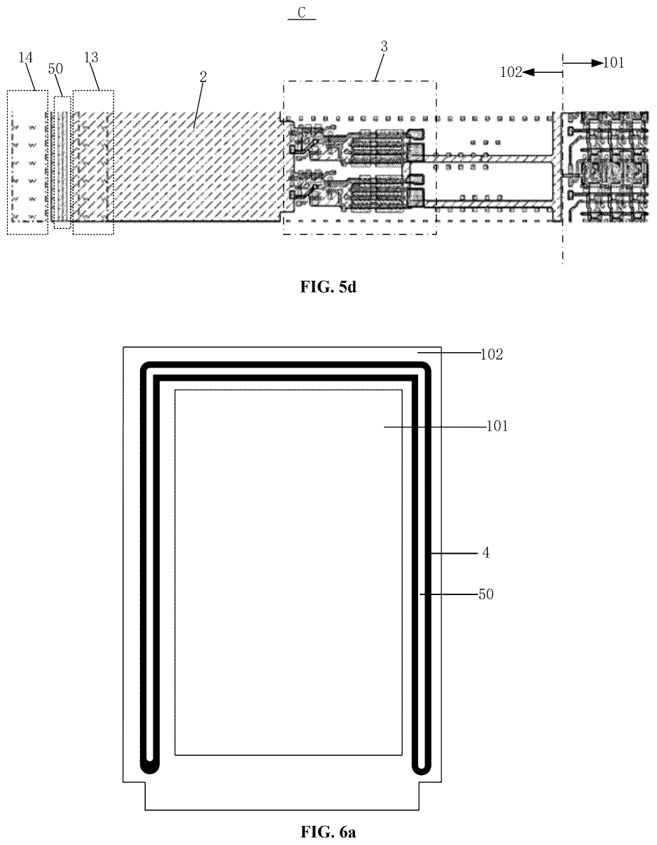

FIG. 5 a is an enlarged top view of a portion C in FIG. 2 a. In some embodiments, referring to FIG. 2b, FIG. 4a, and FIG. 5a, the display panel further includes a first dam 13 and a second dam 14 that are disposed in the frame region 102 and on a side, going away from the substrate 1, of the second conductive layer 42. The first dam 13 and the second dam 14 are spaced apart from each other and successively arranged along the direction away from the display region 101. Orthographic projections of the first dam 13 and the second dam 14 on the substrate 1 are at least partially overlapped with an orthographic projection of the first potential line 4 on the substrate 1, and an orthographic projection of the first opening 50 on the substrate 1 is between the orthographic projections of the first dam 13 and the shift register circuit 3 on the substrate 1.

FIG. 5b is still another schematic structural diagram of a section along a section line AA′ in FIG. 2a. FIG. 5c is yet still another schematic diagram of a section along a section line AA′ in FIG. 2a. FIG. 5d is another enlarged top view of a portion C in FIG. 2a. In some embodiments, referring to FIGS. 5b, 5c, and 5d, the display panel further includes a first dam 13 and a second dam 14 that are disposed in the frame region 102 and on a side, going away from the substrate 1, of the second conductive layer 42. The first dam 13 and the second dam 14 are spaced apart from each other and successively arranged along the direction away from the display region 101. Orthographic projections of the first dam 13 and the second dam 14 on the substrate 1 are at least partially overlapped with an orthographic projection of the first potential line 4 on the substrate 1, and an orthographic projection of the first opening 50 on the substrate 1 is between the orthographic projections of the first dam 13 and the second dam 14 on the substrate 1.

In some embodiments, referring to FIG. 2b, FIG. 4a, FIG. 5b, and FIG. 5c, the first dam 13 and the second dam 14 are disposed in the same layer as the second insulative layer 8.

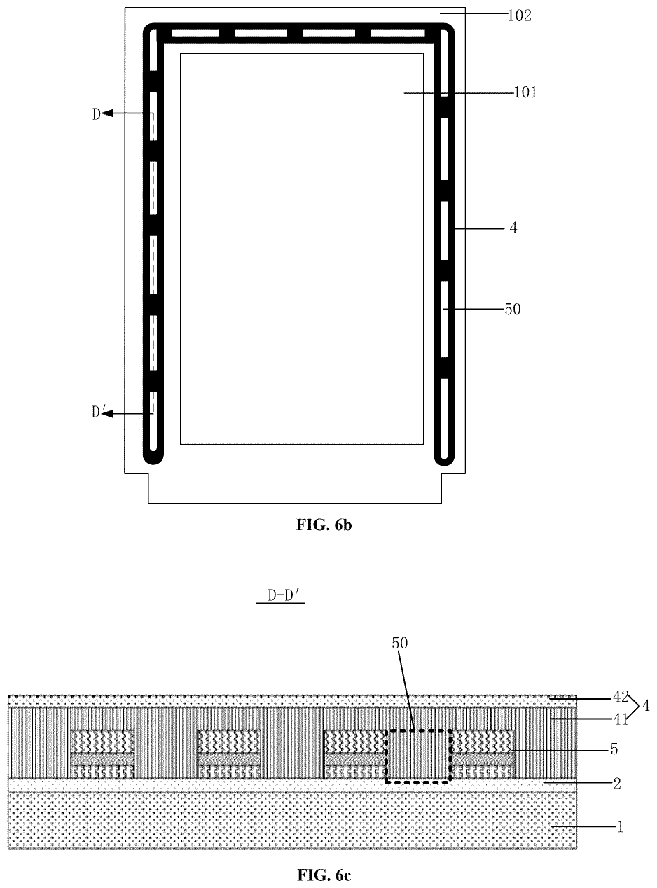

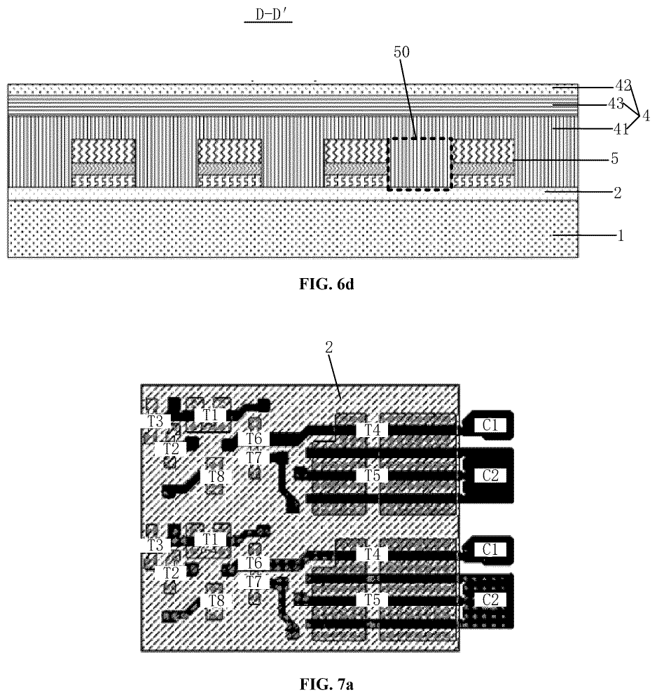

In some embodiments, referring to FIG. 6a, FIG. 6a is another top view of a display panel according to some embodiments of the present disclosure, the first potential line 4 surrounds at least three sides of the frame region 102 outside of the display region 101. The first openings 50 are continuously distributed along an extension direction of the first potential line 4.

FIG. 6b is still another top view of a display panel according to some embodiments of the present disclosure. FIG. 6c is a schematic structural diagram of a section along a section line DD′ in FIG. 6b. FIG. 6d is a schematic structural diagram of a section along a section line DD′ in FIG. 6b. In some embodiments, referring to FIG. 6b, FIG. 6c, and FIG. 6d, the first potential line 4 surrounds at least three sides of the frame region 102 outside of the display region 101. A plurality of first openings 50 are provided, and the plurality of first openings 50 are successively spaced apart along an extension direction of the first potential line 4.

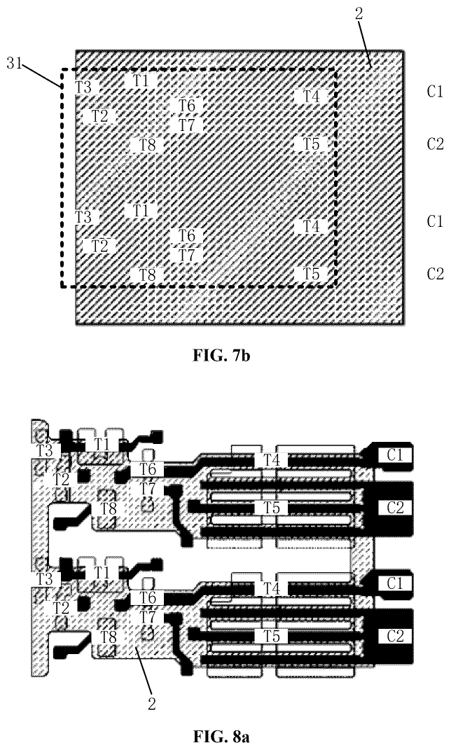

FIG. 7a is a local top view of a region where a shift register circuit is disposed according to some embodiments of the present disclosure. FIG. 7b is another local top view of a region where a shift register circuit is disposed according to some embodiments of the present disclosure. In some embodiments, referring to FIG. 7a and FIG. 7b, the conductive shielding layer 2 disposed in the frame region 102 is planar, and an orthographic projection of the conductive shielding layer 2 on the substrate 1 at least covers the orthographic projections of all of the first-type transistors 31 in the shift register circuit 3 on the substrate 1. Designing the conductive shielding layer 2 to be planar has the advantage of a better shielding effect, while the disadvantage is that the large sheet of metal is at risk of electrostatic discharge (ESD) during the process. ESD risk is lower with a hollowed-out design.

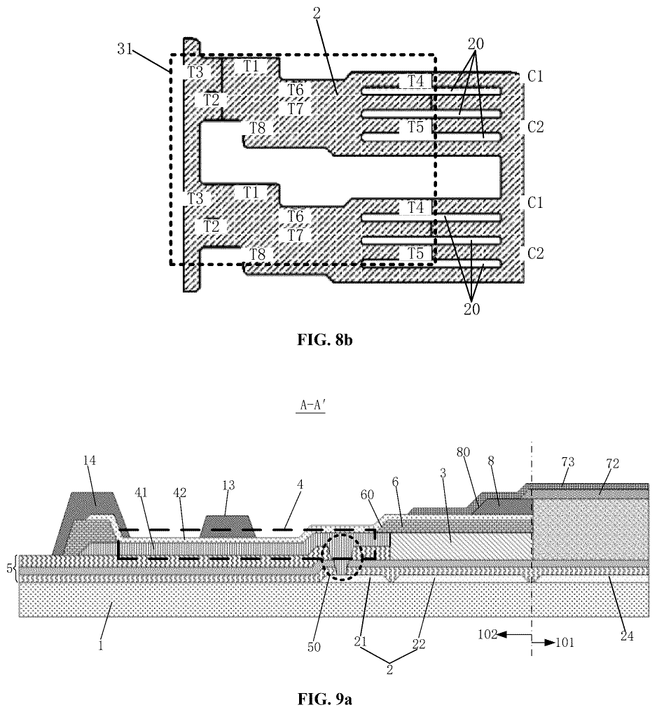

FIG. 8a is still another local top view of a region where a shift register circuit is disposed according to some embodiments of the present disclosure. FIG. 8b is yet still another local top view of a region where a shift register circuit is disposed according to some embodiments of the present disclosure. In some embodiments, referring to FIG. 8a and FIG. 8b, a plurality of hollowed-out portions 20 are opened in the conductive shielding layer 2 disposed in the frame region 102, and an orthographic projection of a region, other than the hollowed-out portions 20, of the conductive shielding layer 2 on the substrate 1 at least covers the orthographic projections of all of the first-type transistors 31 in the shift register circuit 3 on the substrate 1. By designing the hollowed-out portion 20 of the conductive shielding layer 2, the ESD risk during the process is small.

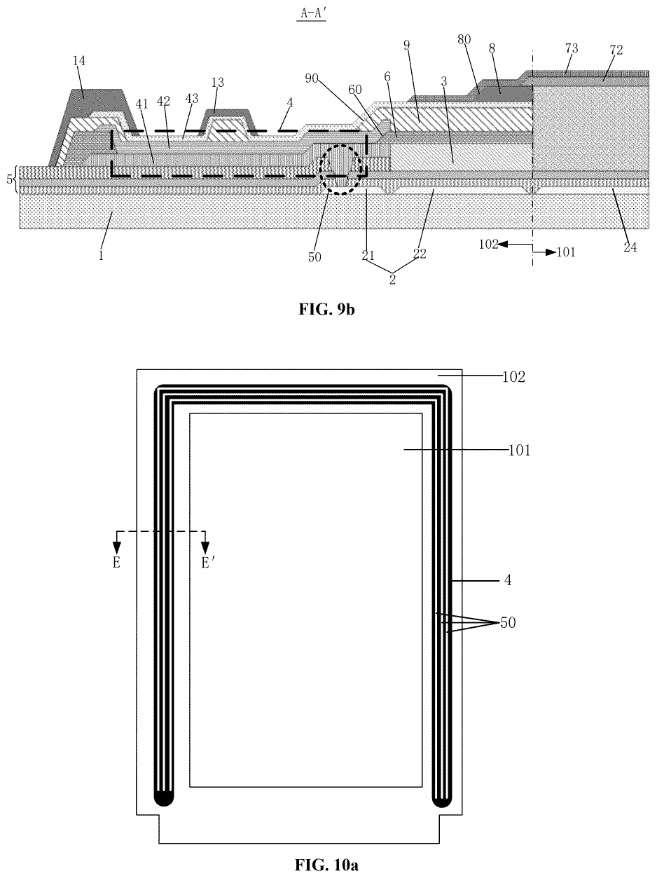

FIG. 9a is yet still another schematic diagram of a section along a section line AA′ in FIG. 2a. FIG. 9b is yet still another schematic diagram of a section along a section line AA′ in FIG. 2a. In some embodiments, referring to FIGS. 9a and 9b, the conductive shielding layer 2 disposed in the frame region 102 includes a first region 21 and a second region 22. The first region 21 and the second region 22 are discontiguous from each other. An orthographic projection of the first region 21 on the substrate is at least partially overlapped with an orthographic projection of the first conductive layer 41 on the substrate 1, and an orthographic projection of the second region 22 on the substrate is at least partially overlapped with an orthographic projection of the shift register circuit 3 on the substrate 1. The first region 21 is electrically connected to the first conductive layer 41 via the first opening 50, and the second region 22 is electrically connected to the second potential line.

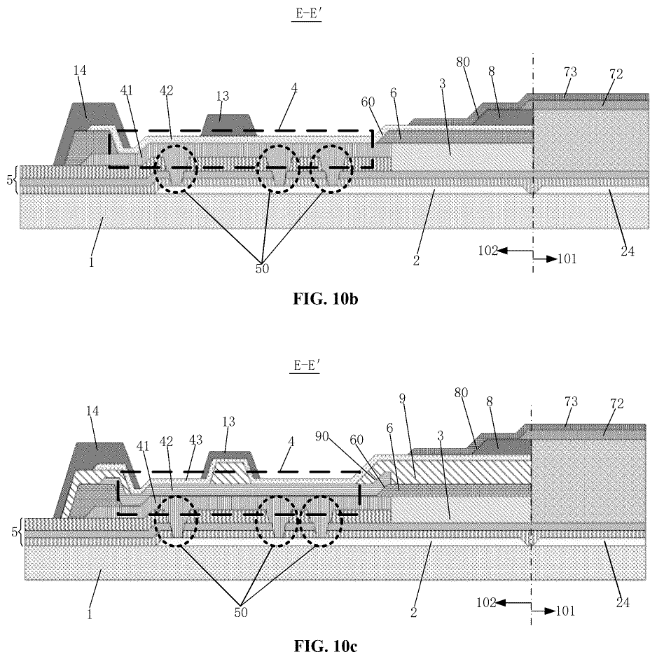

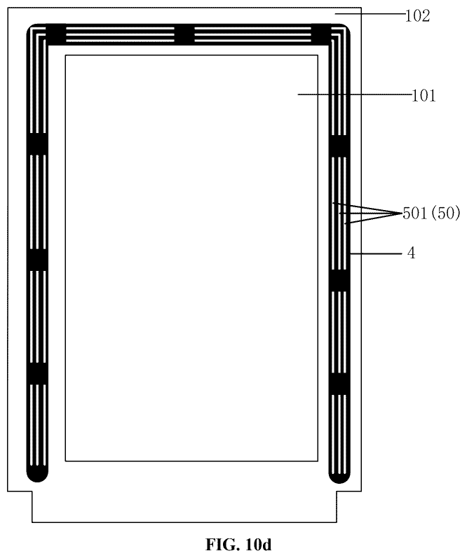

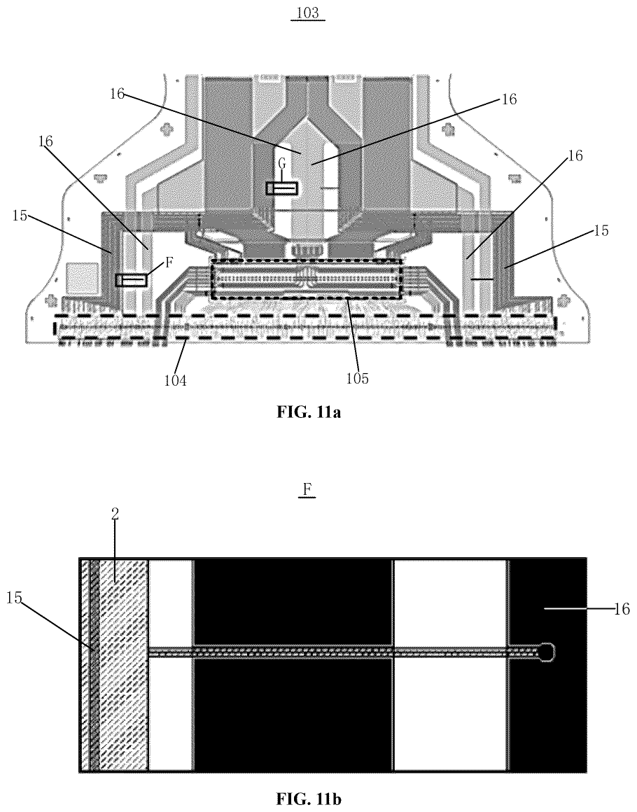

FIG. 10a is yet still another top view of a display panel according to some embodiments of the present disclosure. FIG. 10b is a schematic structural diagram of a section along a section line EE′ in FIG. 10a. FIG. 10c is another schematic structural diagram of a section along a section line EE′ in FIG. 10a. In some embodiments, referring to FIG. 10a, FIG. 10b, and FIG. 10c, a plurality of first openings 50 are provided. The plurality of first openings 50 are successively spaced apart along a line width direction, away from the display region 101, of the first potential line 4. In this case, multiple shields are formed for the shift register circuit 3 along the line width direction, away from the display region 101, of the first potential line 4, such that the shift register circuit 3 is better protected from being affected by accumulated static electricity.

In some embodiments, referring to FIG. 10a, the first potential line 4 surrounds at least three sides of the frame region 102 outside of the display region 101. Each of the first openings 50 is continuously distributed along the extension direction of the first potential line 4.

FIG. 10d is yet still another top view of a display panel according to some embodiments of the present disclosure. In some embodiments, referring to FIG. 10d, the first potential line 4 surrounds at least three sides of the frame region 102 outside of the display region 101. Each of the first openings 50 includes a plurality of sub-openings 501, and the plurality of sub-openings 501 of each of the first openings 50 are all successively spaced apart along the extension direction of the first potential line 4.

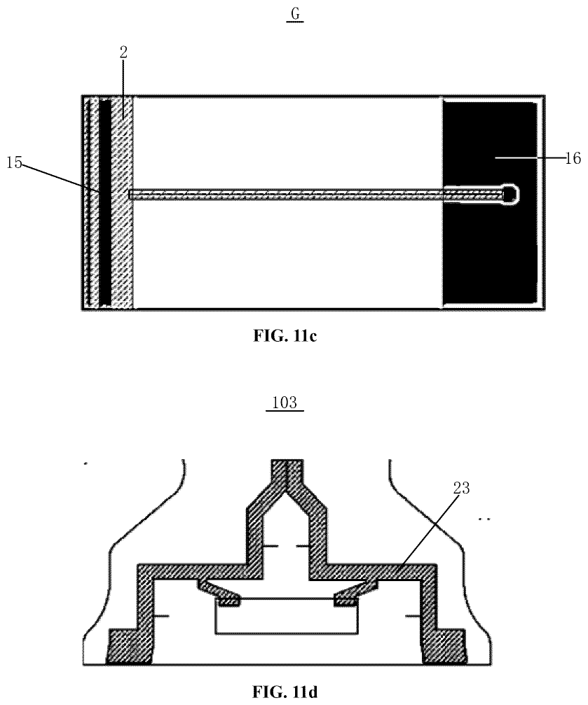

FIG. 11a is a top view of a bonding connecting region of a display panel according to some embodiments of the present disclosure. FIG. 11b is an enlarged schematic diagram of a portion F of FIG. 11a. FIG. 11c is an enlarged schematic diagram of a portion G of FIG. 11 a. FIG. 11d is a top view of a third region of a conductive shielding layer within a bonding connecting region of a display panel according to some embodiments of the present disclosure. In some embodiments, referring to FIG. 2a, the display panel further has a bonding connecting region 103 disposed at least one side of the frame region 102 outside of the display region 101. The display panel further includes a plurality of first traces 15 and a plurality of second potential lines 16. The plurality of first traces 15, the plurality of second potential lines 16, and the first potential line 4 are at least locally disposed in the bonding connecting region 103. The plurality of first traces 15 and the plurality of second potential lines 16 are disposed on the side, going away from the substrate, the conductive shielding layer 2. The plurality of first traces 15 are electrically connected to the shift register circuit 3. The conductive shielding layer 2 further includes a third region 23. An orthographic projection of the third region 23 on the substrate 1 is within the bonding connecting region 103. The orthographic projection of the third region 23 on the substrate 1 at least covers orthographic projections of the plurality of first traces 15 on the substrate 1. The third region 23 is discontiguous from the first region 21 and the second region 22. The third region 23 is electrically connected to the second potential line 16 disposed in the bonding connecting region 103.

In some embodiments, the third region 23 is electrically connected to the first potential line 4 disposed in the bonding connecting region 103.

The third region 23 forms a shield for the plurality of first traces 15 distributed within the bonding connecting region 103, such that the static electricity accumulated on the back side of the substrate 1 is prevented from affecting the shift register circuit 3, and thus the display panel is prevented from occurring the screen flicker defect. The shielding function of the third region 23 is better when being electrically connected to the second potential line 16 or the first potential line 4. A potential signal on the second potential line 16 is a high potential signal, such as VDD. The potential of the second potential line 16 is higher than the potential of the first potential line 4.

In some embodiments, the first traces 15 within the bonding connecting region 103 are selectively blocked and shielded by providing a pattern of the conductive shielding layer 2. In some embodiments, the bonding connecting region 103 includes a peripheral circuit board (i.e., FPC) bonding pad region 104 and a driver chip (IC) bonding pad region 105. The bonding connection between the display panel and the peripheral circuit board is achieved by the peripheral circuit board (i.e., FPC) bonding pad region 104, and the bonding connection between the display panel and the driver chip (such as a data driver chip and a shift register circuit driver chip) is achieved by the driver chip (IC) bonding pad region 105.

In some embodiments, the second potential line 16 is disposed in the same layer as the first conductive layer 41 or the third conductive layer 43. The first trace 15 and the first conductive layer 41 are disposed in the same layer.

In some embodiments, referring to FIG. 2b, FIG. 3b, FIG. 4a, FIG. 5b, FIG. 5c, FIG. 6c, FIG. 6d, FIG. 9a and FIG. 9b, and FIG. 10b and FIG. 10c, the conductive shielding layer 2 further includes a fourth region 24. An orthographic projection of the fourth region 24 on the substrate 1 is within the display region 101 and covers orthographic projections of at least a portion of the second-type transistors 12 on the substrate 1. The fourth region 24 is discontiguous from the first region 21, the second region 22, and the third region 23, and the fourth region 24 is electrically connected to the second potential line 16.

The fourth region 24 of the conductive shielding layer 2 forms a block and shield for at least a portion of the second-type transistors 12, such that the static electricity accumulated on the back side of the substrate 1 is prevented from affecting the characteristics of at least a portion of the second-type transistors 12, and thus a good display quality of the display panel is ensured. The fourth region 24 better serves to shield the surrounding electric field when being electrically connected to the second potential line 16.

In the display panel according to the embodiments of the present disclosure, the conductive shielding layer 2 is arranged beneath the shift register circuit 3, the orthographic projection of the conductive shielding layer 2 on the substrate 1 covers the orthographic projections of at least a portion of the first-type transistors in the shift register circuit 3 on the substrate 1, and at least a local region of the conductive shielding layer 2 is electrically connected to the first potential line 4 via the first opening 50. In this way, the at least a local region of the conductive shielding layer 2 has the first potential, and at the same time, the at least a local region of the conductive shielding layer 2 and the first potential line 4 in the first opening 50 are connected and enclosed to form the three-dimensional shielding structure, which is capable of forming a shield for at least a portion of the first-type transistors in the shift register circuit 3. In this case, the static electricity accumulated on the back side of the substrate 1 is prevented from affecting the characteristics of the at least a portion of the first-type transistors, such that the screen flicker defect of the display panel is prevented, and at the same time, the anti-static capability of the display panel is enhanced, and the anti-static capability of the display panel to prevent screen flicker is improved.

In a second aspect, some embodiments of the present disclosure further provide a method for preparing the display panel described above. The method includes: preparing a conductive shielding layer on a substrate; and

preparing a first insulative layer, a shift register circuit, and a first potential line on a side, going away from the substrate, of the conductive shielding layer.

Preparing the shift register circuit includes preparing a plurality of first-type transistors, wherein an orthographic projection of the conductive shielding layer on the substrate covers orthographic projections of at least a portion of the first-type transistors on the substrate. Preparing the first insulative layer includes preparing a pattern of a first opening, wherein at least a local region of the conductive shielding layer is electrically connected to the first potential line via the first opening.

In some embodiments, the conductive shielding layer is made of a conductive metallic material, such as molybdenum, aluminum, or copper. A pattern of the conductive shielding layer is prepared by a patterning process. The patterning process includes steps of depositing, film-forming, exposing, developing, etching, and the like. The specific processes are mature technologies in the field, which are not repeated herein.

In some embodiments, each conductive film layer in the shift register circuit and the pixel circuit and each insulative film layer disposed between adjacent conductive film layers are successively prepared from bottom to top on the side, going away from the substrate, of the conductive shielding layer. During this process, each film layer in the first insulative layer and a first conductive layer and a third conductive layer of the first potential line are prepared simultaneously, and then a light-emitting element is prepared on a side, going away from the substrate, of the pixel circuit. The preparation of the light-emitting element specifically includes: successively preparing a first electrode, a pixel defining layer, a support spacer layer, a light-emitting function layer, and a second electrode on the substrate where the pixel circuit is formed, and then subsequently preparing a package layer to package the light-emitting element.

In some embodiments, in forming the first opening in the first insulative layer, an opening in some film layers, farther away from the substrate, of the first insulative layer (e.g., an intermediate dielectric layer, a third gate insulative layer, a second buffer layer, a second gate insulative layer, and a first gate insulative layer) is first formed by a one-time masking process, and then an opening in other film layers, closer to the substrate, of the first insulative layer (e.g., a first buffer layer and an inorganic insulative layer) is formed by a one-time masking process. The openings in the two portions of film layers of the first insulative layer together form the first opening in the first insulative layer. The masking process includes steps of photoresist coating, exposure, developing, and etching (e.g., dry etching).

In the embodiments, the specific processes for preparing each film layer in the display panel are mature technologies in the field, which are not repeated herein.

In a third aspect, some embodiments of the present disclosure further provide a display device. The display device includes the display panel as described above.

By adopting the display panel as described above, the anti-static capability of the display device is enhanced, and the display quality of the display device is improved.

The display device is a wearable display product such as a watch, a bracelet, or the like.

The display device according to the embodiments of the present disclosure is an OLED panel, an OLED TV, an OLED billboard, a monitor, a smartphone, a navigator, or any other product or component with a display function.

It should be noted that described above are merely exemplary embodiments of the present disclosure for explaining the principles of the present disclosure, and are not intended to limit the present disclosure. Therefore, for those skilled in the art, any modifications, equivalent substitutions, improvements, and the like made without departing from the spirit and principles of the present disclosure shall be included in the protection scope of the present disclosure.

1. A display panel, having a display region and a frame region, wherein the frame region surrounds the display region, and the display panel comprises:
a substrate;
a conductive shielding layer disposed on a side of the substrate, wherein an orthographic projection of the conductive shielding layer on the substrate is at least within the frame region;
a shift register circuit disposed in the frame region and on a side, going away from the substrate, of the conductive shielding layer;
a first potential line disposed in the frame region and on the side, going away from the substrate, of the conductive shielding layer; and
a first insulative layer disposed between the conductive shielding layer and the first potential line and the shift register circuit; wherein
the shift register circuit and the first potential line are successively arranged along a direction away from the display region;
the shift register circuit comprises a plurality of first-type transistors, and the orthographic projection of the conductive shielding layer on the substrate covers orthographic projections of at least a portion of the first-type transistors on the substrate; and
the orthographic projection of the conductive shielding layer on the substrate is at least partially overlapped with an orthographic projection of the first potential line on the substrate, a first opening is formed in the first insulative layer, an orthographic projection of the first opening on the substrate being within an overlap region between the orthographic projections of the conductive shielding layer and the first potential line, and at least a local region of the conductive shielding layer is electrically connected to the first potential line via the first opening.

2. The display panel according to claim 1, wherein the first potential line comprises a first conductive layer and a second conductive layer, wherein the first conductive layer and the second conductive layer are stacked successively away from the substrate, an orthographic projection of the first conductive layer on the substrate being at least partially overlapped with an orthographic projection of the second conductive layer on the substrate, and the first conductive layer is electrically connected to at least a local region of the conductive shielding layer via the first opening; and
the display panel further comprises a first planarization layer disposed between the first conductive layer and the second conductive layer, wherein a second opening is formed in the first planarization layer, an orthographic projection of the second opening on the substrate being within an overlap region between the orthographic projections of the first conductive layer and the second conductive layer, and the first conductive layer is electrically connected to the second conductive layer via the second opening.

3. The display panel according to claim 1, wherein
the first potential line comprises a first conductive layer, a second conductive layer, and a third conductive layer, wherein the first conductive layer, the third conductive layer, and the second conductive layer are stacked successively away from the substrate, orthographic projections of any adjacent two of the first conductive layer, the third conductive layer, and the second conductive layer on the substrate being at least partially overlapped, and the first conductive layer is electrically connected to at least a local region of the conductive shielding layer via the first opening;
the display panel further comprises a first planarization layer disposed between the first conductive layer and the third conductive layer, wherein a second opening is formed in the first planarization layer, an orthographic projection of the second opening on the substrate being within an overlap region between the orthographic projections of the first conductive layer and the third conductive layer, and the first conductive layer is electrically connected to the third conductive layer via the second opening; and
the display panel further comprises a second planarization layer disposed between the third conductive layer and the second conductive layer, wherein a third opening is formed in the second planarization layer, an orthographic projection of the third opening on the substrate being within an overlap region between the orthographic projections of the second conductive layer and the third conductive layer, and the third conductive layer is electrically connected to the second conductive layer via the third opening.

4. The display panel according to claim wherein each of the first-type transistors comprises a gate electrode, an active layer, a first electrode, and a second electrode, wherein the first electrode and the second electrode are disposed in a same layer, the gate electrode, the active layer, and the first electrode are respectively disposed in different layers, and the first conductive layer, the first electrode, and the second electrode are disposed in a same layer;
the display panel further comprises a light-emitting element disposed in the display region, wherein the light-emitting element comprises a first electrode, a light-emitting functional layer, and a second electrode that are stacked successively away from the substrate, the second conductive layer and the first electrode are disposed in a same layer, the second electrode extends to the frame region, and an orthographic projection of second electrode on the substrate is partially overlapped with the orthographic projection of the second conductive layer on the substrate; and
the display panel further comprises a second insulative layer disposed between the first electrode and the second electrode, wherein the second insulative layer extends from the display region to the frame region, a fourth opening is formed in a portion, disposed in the frame region, of the second insulative layer, and the second electrode is electrically connected to the second conductive layer via the fourth opening.

5. The display panel according to claim 4, further comprising: a pixel circuit disposed in the display region and between the light-emitting element and the substrate; wherein
the pixel circuit comprises a conductive connecting structure and a plurality of second-type transistors, wherein the plurality of second-type transistors and the plurality of first-type transistors are disposed in a same layer, and the conductive connecting structure is disposed on a side, going away from the substrate, of the second-type transistors;
the first planarization layer extends between the second-type transistors and the conductive connecting structure, wherein a fifth opening is formed in a portion, disposed in the display region, of the first planarization layer, and a first electrode of each of the second-type transistors is electrically connected to the conductive connecting structure via the fifth opening;
the second planarization layer extends between the conductive connecting structure and the first electrode, wherein a sixth opening is formed in a portion, disposed in the display region, of the second planarization layer, and the conductive connecting structure is electrically connected to the first electrode via the sixth opening; and
the third conductive layer and the conductive connecting structure are disposed in a same layer.

6. The display panel according to claim 4, further comprising: a first dam and a second dam that are disposed in the frame region and on a side, going away from the substrate, of the second conductive layer; wherein
the first dam and the second dam are successively arranged and spaced apart from each other along the direction away from the display region, and orthographic projections of the first dam and the second dam on the substrate are at least partially overlapped with the orthographic projection of the first potential line on the substrate; and
the orthographic projection of the first opening on the substrate is disposed between the orthographic projection of the first dam on the substrate and an orthographic projection of the shift register circuit on the substrate.

7. The display panel according to claim 4, further comprising: a first dam and a second dam that are disposed in the frame region and on a side, going from the substrate, of the second conductive layer; wherein
the first dam and the second dam are successively arranged and spaced apart from each other along the direction away from the display region, and orthographic projections of the first dam and the second dam on the substrate are at least partially overlapped with the orthographic projection of the first potential line on the substrate; and
the orthographic projection of the first opening on the substrate is disposed between the orthographic projections of the first dam and the second dam on the substrate.

8. The display panel according to claim 6, wherein
the first potential line surrounds at least three sides of the frame region outside of the display region; and
the first openings are continuously distributed along an extension direction of the first potential line.

9. The display panel according to claim 6, wherein
the first potential line surrounds at least three sides of the frame region outside of the display region; and
a plurality of the first openings are provided, wherein the plurality of the first openings are spaced apart successively along an extension direction of the first potential line.

10. The display panel according to claim 1, wherein
the conductive shielding layer disposed in the frame region is planar; and
the orthographic projection of the conductive shielding layer on the substrate at least covers orthographic projections of all of the first-type transistors in the shift register circuit on the substrate.

11. The display panel according to claim 1, wherein
a plurality of hollowed-out portions are formed in the conductive shielding layer disposed in the frame region; and
an orthographic projection of a region, other than the plurality of hollowed-out portions, of the conductive shielding layer on the substrate at least covers orthographic projections of all of the first-type transistors in the shift register circuit on the substrate.

12. The display panel according to claim 5, wherein the conductive shielding layer disposed in the frame region comprises a first region and a second region, the first region and the second region being discontiguous from each other; wherein
an orthographic projection of the first region on the substrate is at least partially overlapped with an orthographic projection of the first conductive layer on the substrate, and an orthographic projection of the second region on the substrate is at least partially overlapped with an orthographic projection of the shift register circuit on the substrate; and
the first region is electrically connected to the first conductive layer via the first opening, and the second region is electrically connected to a second potential line.

13. The display panel according to claim 2, wherein a plurality of the first openings are provided, the plurality of the first openings being successively spaced apart along a line width direction, away from the display region, of the first potential line.

14. The display panel according to claim 13, wherein
the first potential line surrounds at least three sides of the frame region outside of the display region; and
each of the first openings is continuously distributed along an extension direction of the first potential line.

15. The display panel according to claim 13, wherein
the first potential line surrounds at least three sides of the frame region outside of the display region; and
each of the first openings comprises a plurality of sub-openings, the plurality of sub-openings of each of the first openings being spaced apart successively along the extension direction of the first potential line.

16. The display panel according to claim 12, further comprising: a bonding connecting region disposed at least one side of the frame region outside of the display region; wherein
the display panel further comprises a plurality of first traces and a plurality of the second potential lines, wherein the plurality of first traces, the plurality of the second potential lines, and the first potential line are at least partially disposed in the bonding connecting region, the plurality of first traces and the plurality of the second potential lines are disposed on the side, going away from the substrate, of the conductive shielding layer, and the plurality of first traces are electrically connected to the shift register circuit; and
the conductive shielding layer further comprises a third region, wherein an orthographic projection of the third region on the substrate is disposed in the bonding connecting region, the orthographic projection of the third region on the substrate at least covers orthographic projections of the plurality of first traces on the substrate, the third region is discontiguous from the first region and the second region, and the third region is electrically connected to the first potential line disposed in the bonding connecting region, or the third region is electrically connected to the second potential line disposed in the bonding connecting region.

17. The display panel according to claim 16, wherein the conductive shielding layer further comprises a fourth region; wherein
an orthographic projection of the fourth region on the substrate is disposed in the display region;
the orthographic projection of the fourth region on the substrate covers orthographic projections of at least a portion of the second-type transistors on the substrate;
the fourth region is discontiguous from the first region, the second region, and the third region; and
the fourth region is electrically connected to the second potential line.

18. The display panel according to claim 1, wherein the shift register circuit comprises a first gate drive shift register circuit, a light-emitting control shift register circuit, and a second gate drive shift register circuit.

19. A display device, comprising: a display panel; wherein
the display panel has a display region and a frame region, the frame region surrounding the display region; and
the display panel comprises:
a substrate;
a conductive shielding layer disposed on a side of the substrate, wherein an orthographic projection of the conductive shielding layer on the substrate is at least within the frame region;
a shift register circuit disposed in the frame region and on a side, going away from the substrate, of the conductive shielding layer;
a first potential line disposed in the frame region and on the side, going away from the substrate, of the conductive shielding layer; and
a first insulative layer disposed between the conductive shielding layer and the first potential line and the shift register circuit; wherein
the shift register circuit and the first potential line are successively arranged along a direction away from the display region;
the shift register circuit comprises a plurality of first-type transistors, and the orthographic projection of the conductive shielding layer on the substrate covers orthographic projections of at least a portion of the first-type transistors on the substrate; and
the orthographic projection of the conductive shielding layer on the substrate is at least partially overlapped with an orthographic projection of the first potential line on the substrate, a first opening is formed in the first insulative layer, an orthographic projection of the first opening on the substrate being within an overlap region between the orthographic projections of the conductive shielding layer and the first potential line, and at least a local region of the conductive shielding layer is electrically connected to the first potential line via the first opening.

20. A method for preparing a display panel, comprising:
preparing a conductive shielding layer on a substrate; and
preparing a first insulative layer, a shift register circuit, and a first potential line on a side, going from the substrate, of the conductive shielding layer; wherein
preparing the shift register circuit comprises preparing a plurality of first-type transistors, wherein an orthographic projection of the conductive shielding layer on the substrate covers orthographic projections of at least a portion of the first-type transistors on the substrate; and
preparing the first insulative layer comprises preparing a pattern of a first opening, wherein at least a local region of the conductive shielding layer is electrically connected to the first potential line via the first opening.
